(19) United States
(12) Patent Application Publication
(10) Pub. No.: US 2012/0031560 A1
(43) Pub. Date: Feb. 9, 2012

(54) PLASMA PROCESSING APPARATUS

(75) Inventor: Chishio Koshimizu, Nirasaki (JP)

(73) Assignee: TOKYO ELECTRON LIMITED, Tokyo (JP)

(21) Appl. No.: 13/196,193

(22) Filed: Aug. 2, 2011

Related U.S. Application Data
(60) Provisional application No. 61/375,562, filed on Aug. 20, 2010.

(30) Foreign Application Priority Data
Aug. 4, 2010 (JP) 2010-175401

(51) Int. Cl. H01L 21/3065; C23C 16/50

(52) U.S. Cl. 156/345.33; 118/723 MP

(57) ABSTRACT

A plasma processing apparatus includes: an evacuable chamber 11 for performing therein a plasma process on a substrate G; a susceptor 12 for mounting thereon the substrate G within the chamber 11; a dielectric window 30 provided to face the susceptor 12 via a processing space S; RF antennas 30a and 30b disposed in a space adjacent to the processing space S with the dielectric window 30; a gas supply unit 37 for supplying a processing gas into the processing space S; a high frequency power supply for applying a high frequency RF_{H} to the RF antennas 30a and 30b, and generating plasma of the processing gas within the processing space S by an inductive coupling; and a protrusion 34 made of a dielectric material and provided on a bottom surface of the dielectric window 30 corresponding to an inter-position of the RF antennas 30a and 30b.

### CROSS-REFERENCE TO RELATED APPLICATION

This application claims the benefit of Japanese Patent Application No. 2010-175401 filed on Aug. 4, 2010 and U.S. Provisional Application Ser. No. 61/375,562 filed on Aug. 20, 2010, the entire disclosures of which are incorporated herein by reference.

### FIELD OF THE INVENTION

The present disclosure relates to an inductively coupled plasma processing apparatus for performing a plasma process on a substrate.

### BACKGROUND OF THE INVENTION

In a manufacturing process of a semiconductor device or a flat panel display (FPD) such as a liquid crystal display (LCD), there is known a plasma processing apparatus for performing a plasma process on various kinds of substrates such as a glass substrate. The plasma processing apparatus can be classified into a capacitively coupled plasma processing apparatus and an inductively coupled plasma processing apparatus according to a plasma generation method.

In an inductively coupled plasma processing apparatus (hereinafter, simply referred to as an “ICP processing apparatus”), a high frequency power is applied to a high frequency antenna (hereinafter, referred to as a “RF antenna”) via a dielectric member, such as quartz, disposed at a part of the processing chamber. The high frequency antenna has a vortex shape, a coil shape or a spiral shape, and is provided at an outside of a processing chamber (chamber). An induced magnetic field is formed around the RF antenna to which the high frequency power is applied, and plasma of a processing gas is generated by the induced electric field formed within the chamber by the induced magnetic field. A plasma process is performed on the substrate by the generated plasma.

In such an ICP processing apparatus, since the plasma is mainly generated by the induced electric field, high-density plasma can be obtained. Due to this advantage, the ICP processing apparatus has been appropriately used in an etching process or a film forming process in manufacturing a FPD or the like.

Further, recently, there has been developed a technique for effectively preventing foreign substances generated during the plasma process from adhering to the dielectric member disposed within the chamber of the ICP processing apparatus (See, for example, Patent Document 1).
Patent Document 1: Japanese Patent Laid-open Publication No. 2003-209098

In the ICP processing apparatus, however, even if a multiple number of RF antennas are provided and a high frequency power for plasma generation (hereinafter, referred to as an “excitation RF_{H}”) applied to the RF antennas is controlled, it may be difficult to generate plasma so as to be distributed in one-to-one correspondence to the RF antennas. That is, it may be difficult to control a plasma distribution within the chamber as desired.

FIG. 16 provides a cross sectional view of a plasma processing apparatus in order to describe a state in which plasma is generated at positions different from those corresponding to high frequency antennas.

As depicted in FIG. 16, a dielectric member (hereinafter, referred to as a “dielectric window”) 202 is provided in a ceiling portion of a chamber 201 of a plasma processing apparatus 200. Circular ring-shaped RF antennas 203a and 203b are concentrically disposed on or above the dielectric window 202, i.e., in a space adjacent to a processing space S of the chamber 201 via the dielectric window 202. One ends of the circular ring-shaped RF antennas 203a and 203b are connected with high frequency powers 204a and 204b for plasma generation via matching units, respectively, and other ends thereof are grounded.

In this plasma processing apparatus 200, when an excitation RF_{H} is applied to the RF antennas 203a and 203b, double plasma individually corresponding to the two concentric circular ring-shaped RF antennas 203a and 203b may not be generated, but single circular ring-shaped plasma 205 corresponding to an intermediate position between the two circular ring-shaped RF antennas 203a and 203b is generated.

The reason for this phenomenon is deemed to be as follows. If the excitation RF_{H} is applied to the circular ring-shaped RF antennas 203a and 203b, a high frequency current flows in the RF antennas 203a and 203b, and an induced magnetic field 206 is formed around the respective RF antennas 203a and 203b. As a result, the single circular ring-shaped plasma 205 is formed at a position corresponding to a space where a combined induced magnetic field is strong.

That is, in the conventional plasma processing apparatus, it may be difficult to generate plasma in one-to-one correspondence to the RF antennas 203a and 203b. Thus, it may be difficult to control a plasma distribution within the chamber.

### BRIEF SUMMARY OF THE INVENTION

In view of the foregoing, the present disclosure provides a plasma processing apparatus capable of generating plasma in one-to-one correspondence to high frequency antennas according to a high frequency power, and also capable of controlling a plasma distribution within a processing chamber.

To solve the above-mentioned problems, in accordance with one aspect of the present disclosure, there is provided a plasma processing apparatus including an evacuable processing chamber for performing therein a plasma process on a substrate; a substrate mounting table for mounting thereon the substrate within the processing chamber; a dielectric window provided to face the substrate mounting table via a processing space; a multiple number of high frequency antennas disposed in a space adjacent to the processing space with the dielectric window positioned therebetween; a gas supply unit for supplying a processing gas into the processing space; a high frequency power supply for applying a high frequency power to the multiple number of high frequency antennas to thereby generate plasma of the processing gas by an inductive coupling; and a combination preventing member for preventing induced magnetic fields corresponding to the multiple number of high frequency antennas from being combined with each other.

Further, the combination preventing member may be a protrusion made of a dielectric material and provided on a surface of the dielectric window facing the processing space, and the combination preventing member may be located at a position corresponding to an inter-position of the multiple number of high frequency antennas.

Furthermore, a thickness of a portion of the dielectric window corresponding to the multiple number of high frequency antennas may be smaller than that of the other portion of the dielectric window.

A protrusion made of a material having a magnetic permeability different from that of the dielectric window may be provided at an inter-position of the multiple number of high frequency antennas.

Moreover, the protrusion made of a material having a magnetic permeability different from that of the dielectric window may be provided on a surface of the dielectric window facing the processing space or on a surface of the dielectric window opposite to the processing space.

A part of the protrusion made of a material having a magnetic permeability different from that of the dielectric window may be inserted and buried in the dielectric window.

Further, the multiple number of high frequency antennas may be spaced apart from each other at a distance enough for preventing the induced magnetic fields corresponding to the multiple number of high frequency antennas from being combined with each other.

The dielectric window may be divided so as to correspond to the multiple number of high frequency antennas, and a conductor, which is grounded, may be disposed between the divided dielectric windows.

In accordance with the present disclosure, it is possible to generate plasma in one-to-one correspondence to the high frequency antennas according to a high frequency power, and it is also possible to control a plasma distribution within the processing chamber.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a cross sectional view schematically showing a configuration of a plasma processing apparatus in accordance with a first embodiment of the present disclosure;

FIG. 2 is a cross sectional view schematically illustrating a major configuration of a plasma processing apparatus in accordance with a second embodiment of the present disclosure;

FIG. 3 is a cross sectional view schematically illustrating a major configuration of a plasma processing apparatus in accordance with a third embodiment of the present disclosure;

FIG. 4 is a cross sectional view schematically illustrating a major configuration of a modification example of the third embodiment;

FIG. 5 is a cross sectional view schematically illustrating a major configuration of another modification example of the third embodiment;

FIG. 6 is a cross sectional view schematically illustrating a major configuration of a plasma processing apparatus in accordance with a fourth embodiment of the present disclosure;

FIG. 7 is a cross sectional view schematically illustrating a major configuration of a plasma processing apparatus in accordance with a fifth embodiment of the present disclosure;

FIG. 8 is a cross sectional view schematically illustrating a major configuration of a plasma processing apparatus in accordance with a sixth embodiment of the present disclosure;

FIG. 9 is a cross sectional view schematically illustrating a major configuration of a plasma processing apparatus in accordance with a seventh embodiment of the present disclosure;

FIG. 10 is a cross sectional view schematically illustrating a major configuration of a modification example of the seventh embodiment;

FIG. 11 is a cross sectional view schematically illustrating a major configuration of a plasma processing apparatus in accordance with an eighth embodiment of the present disclosure;

FIG. 12 is a cross sectional view schematically illustrating a major configuration of a plasma processing apparatus in accordance with a ninth embodiment of the present disclosure;

FIG. 13 is a cross sectional view schematically illustrating a major configuration of a plasma processing apparatus in accordance with a tenth embodiment of the present disclosure;

FIG. 14 is a cross sectional view schematically illustrating a major configuration of a plasma processing apparatus in accordance with an eleventh embodiment of the present disclosure;

FIG. 15 is a cross sectional view schematically illustrating a major configuration of a plasma processing apparatus in accordance with a twelfth embodiment of the present disclosure; and

FIG. 16 provides a cross sectional view of a plasma processing apparatus in order to describe a state in which plasma is generated at positions different from those corresponding to high frequency antennas.

### DETAILED DESCRIPTION OF THE INVENTION

Hereinafter, non-limiting embodiments of the present disclosure will be described in detail with reference to the accompanying drawings.

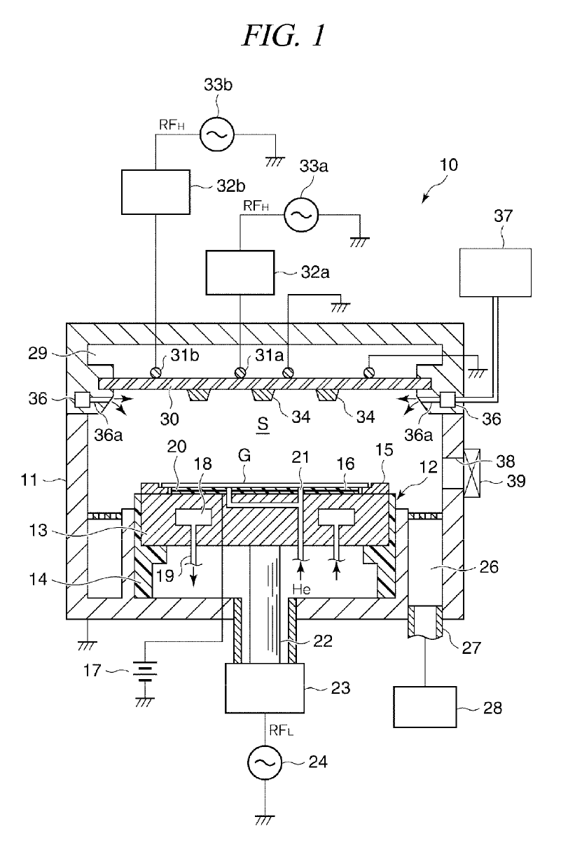

FIG. 1 is a cross sectional view schematically illustrating a configuration of a plasma processing apparatus in accordance with a first embodiment of the present disclosure. This plasma processing apparatus performs a plasma process such as etching process or film forming process on, e.g., a glass substrate for manufacturing a liquid crystal display (LCD).

As depicted in FIG. 1, a plasma processing apparatus may include a processing chamber 11 for accommodating therein a glass substrate to be processed (hereinafter, simply referred to as a “substrate”) G. A cylindrical mounting table (susceptor) 12 for mounting thereon the substrate G is provided in a lower part of the chamber 11. The susceptor 12 may mainly include a base member 13 made of, e.g., aluminum of which surface is alumite-treated, and the base member 13 is supported on a bottom of the chamber 11 with an insulating member 14 provided therebetween. A top surface of the base member 13 is a substrate mounting surface on which the substrate G is mounted, and a focus ring 15 is provided so as to surround the substrate mounting surface.

An electrostatic chuck (ESC) 20 having an electrostatic electrode plate 16 therein may be provided on the substrate mounting surface of the base member 13. The electrostatic electrode plate 16 may be connected with a DC power supply 17. If a positive DC voltage is applied to the electrostatic electrode plate 16, a negative potential may be generated on a surface (hereinafter, referred to as a “rear surface”) of the substrate G facing the electrostatic electrode plate 16. Accordingly, a potential difference may be generated between the electrostatic electrode plate 16 and the rear surface of the substrate G. The substrate G is attracted to and held on the substrate mounting surface by a Coulomb force or a Johnsen-Rahbek force generated due to the potential difference.

A circular ring-shaped coolant cavity 18 is formed in the base member 13 of the susceptor 12 on a circumference. A coolant of a low temperature, such as cooling water or Galden (Registered Trademark) is supplied and circulated into the coolant cavity 18 through a coolant line 19 from a chiller unit (not shown). The susceptor 12 cooled by the coolant may cool the substrate G and the focus ring 15 via the electrostatic chuck 20.

A multiple number of heat transfer gas supply holes are formed in the base member 13 and the electrostatic chuck 20. Each heat transfer gas supply hole 21 is connected with a non-illustrated heat transfer gas supply unit, and a heat transfer gas such as a helium (He) gas is supplied into a gap between the electrostatic chuck 20 and the rear surface of the substrate G. The He gas supplied into the gap between the electrostatic chuck 20 and the rear surface of the substrate G transfers heat of the substrate G to the susceptor 12, effectively.

A high frequency power supply 24 for supplying a high frequency power for biasing (hereinafter, referred to as a “bias RF_{L}”) may be connected to the base member 13 of the susceptor 12 via a matching unit 23 and a power supply rod 22. The susceptor 12 serves as a lower electrode and the matching unit 23 reduces reflection of a high frequency power from the susceptor 12, thus maximizing the efficiency of applying the high frequency power to the susceptor 12. A bias RF_{L} equal to or less than about 40 MHz, e.g., about 13.56 MHz, may be applied to the susceptor 12 from the high frequency power supply 24, so that plasma generated in the processing space S is attracted toward the substrate G.

In the plasma processing apparatus 10, a side exhaust path 26 is formed between an inner sidewall of the chamber 11 and a side surface of the susceptor 12. The side exhaust path 26 is connected with a gas exhaust unit 28 via an exhaust line 27. The gas exhaust unit 28 may include a TMP (Turbo Molecular Pump) and a DP (Dry Pump) (both are not shown), and evacuates and depressurizes the inside of the chamber 11. To elaborate, the DP may depressurize the inside of the chamber 11 from an atmospheric pressure to an intermediate vacuum state (e.g., about 1.3×10 Pa (0.1 Torr) or less), and the TMP may further depressurize the inside of the chamber 11 to a high vacuum state (e.g., about 1.3×10⁻⁵ Pa (1.0×10⁻⁵ Torr) or less) lower than the intermediate vacuum state in cooperation with the DP. Further, an internal pressure of the chamber 11 may be controlled by an APC value (not shown).

A dielectric window 30 is provided at a ceiling portion of the chamber 11 so as to face the susceptor 12 via the processing space S. The dielectric window 30 is made of, e.g., a quartz plate and is airtightly sealed. Further, the dielectric window 30 transmits magnetic force lines. In an upper space 29 above the dielectric window 30, circular ring-shaped RF antennas 31a and 31b may be concentrically arranged and may be coaxially positioned with respect to, e.g., the susceptor 12. The circular ring-shaped RF antennas 31a and 31b are fixed on a surface (hereinafter, referred to as a “top surface”) of the dielectric window 30 opposite to the processing space S by a fixing member (not shown) made of, e.g., an insulator.

One ends of the RF antennas 31a and 31b are electrically connected with high frequency power supplies 33a and 33b for plasma generation via matching units 32a and 32b, respectively. Other ends of the RF antennas 31a and 31b are grounded. The high frequency power supplies 33a and 33b output, by a high frequency discharge, a high frequency power RF_{H} having a frequency of, e.g., about 13.56 MHz suitable for plasma generation, and apply the outputted high frequency power RF_{H} to the RF antennas 31a and 31b. The matching units 32a and 32b have the same function as that of the matching unit 23.

An annular manifold 36 may be formed in a sidewall of the chamber 11 below the dielectric window 30 along an inner periphery of the chamber 11. The annular manifold 36 is connected with a processing gas supply source 37 via a gas flow path. The manifold 36 is provided with, by way of example, a multiple number of gas discharge openings 36a arranged at a regular distance. A processing gas introduced into the manifold 36 from the processing gas supply source 37 is supplied into the chamber 11 through the gas discharge openings 36a.

The plasma processing apparatus 10 may further include a combination preventing member for preventing induced magnetic fields formed around the RF antennas 31a and 31b from being combined with each other. Here, the high frequency powers are applied to the RF antennas 31a and 31b from the high frequency powers supplies 33a and 33b.

That is, protrusions 34 made of a dielectric material are provided on a surface (hereinafter, referred to as a “bottom surface”) of the dielectric window 30 facing the processing space S. To elaborate, each protrusion 34 is located at a position corresponding to an inter-position of the circular ring-shaped RF antennas 31a and 31b. Here, the term “inter-position of RF antennas” is a wide term including not only a gap between independent RF antennas but also a gap in a vortex or a spiral of a vortex-shaped or a spiral-shaped RF antenna. Further, the term of “inter-position of RF antennas” also includes a central area of the circular ring-shaped RF antenna. Hereinafter, the term “inter-position of RF antenna” has the above-mentioned meaning over the whole disclosure. By way of example, yttria, alumina, or the like can be used as the dielectric material for forming the protrusion 34 and, desirably, glass may be used appropriately. Since the protrusion 34 physically occupies a position where a combined magnetic field may be formed, plasma caused by the combined magnetic field cannot exist. As a result, plasma may be generated at a position corresponding to the respective RF antennas 31a and 31b.

A substrate loading/unloading port 38 is formed in the sidewall of the chamber 11. The substrate loading/unloading port 38 can be opened and closed by a gate valve 39. The substrate G to be processed is loaded into and unloaded from the chamber 11 via the substrate loading/unloading port 38.

In the plasma processing apparatus 10 having the above-described configuration, a processing gas is supplied into the processing space S of the chamber 11 from the processing gas supply source 37 via the manifold 36 and the gas discharge openings 36a. Further, the excitation RF_{H} is applied to the RF antennas 31a and 31b from the high frequency power supplies 33a and 33b via the matching units 32a and 32b, respectively, so that high frequency current flows in the RF antennas 31a and 31b. As the high frequency current flows, an induced magnetic field is formed around the RF antennas 31a and 31b. Further, an induced electric field is formed in the processing space S due to the induced magnetic field. Electrons accelerated by the induced electric field collide with molecules or atoms of the processing gas. Thus, the processing gas is ionized and excited into plasma by the induced electric field.

Ions in the generated plasma are attracted toward the substrate G by the bias RF_{L} applied to the susceptor 12 from the high frequency power supply 24 via the matching unit 23 and the power supply rod 22, so that a plasma process is performed on the substrate G.

An operation of each component of the plasma processing apparatus 10 may be controlled by a CPU of a controller (not shown) included in the plasma processing apparatus 10 according to a program for the plasma process.

In accordance with the first embodiment as described above, the protrusions 34 made of glass and having circular ring shapes or circular shapes may be provided on the bottom surface of the dielectric window 30 at positions corresponding to the inter-position of the RF antennas 31a and 31b. Specifically, the protrusions 34 may be provided at the positions corresponding to the gap between the RF antennas 31a and 31b, and the central space of the circular ring-shaped RF antenna 31a. Accordingly, plasma cannot exist at positions where a combined magnetic field may be formed by the induced magnetic field generated around the RF antenna 31a and the induced magnetic field generated around the RF antenna 31b. As a consequence, the induced magnetic fields corresponding to the RF antenna 31a and the RF antenna 31b, respectively can be maintained, and the induced electric field may be generated by the respective induced magnetic fields. Accordingly, due to the induced electric field, the plasma corresponding to the respective RF antennas 31a and 31b may be generated according to the applied high frequency power RF_{H}.

In accordance with the first embodiment, by disposing a RF antenna at a position within the chamber 11 corresponding to a position in which plasma needs to be generated and by adjusting the high frequency power RF_{H} applied to this RF antenna, it is possible to control a plasma distribution within the chamber 11.

In accordance with the first embodiment, the protrusions 34 made of the dielectric material may be made of the same material as a material of the dielectric window 30 as a single body therewith, or the protrusions 34 may be made of a material different from the material of the dielectric window 30 as a separate body therefrom.

In accordance with the first embodiment, by way of example, a manifold may be formed in the circular ring-shaped or circular protrusion 34 made of the dielectric material. In such a case, the protrusion 34 may serve as a gas introduction member.

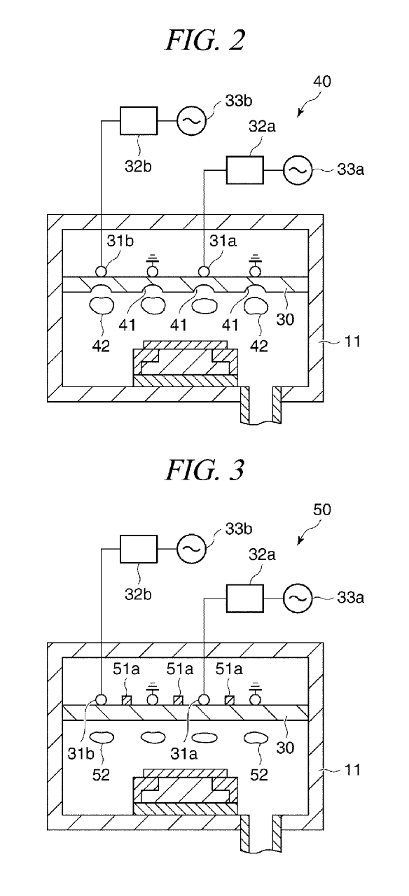

FIG. 2 is a cross sectional view schematically illustrating a major configuration of a plasma processing apparatus in accordance with a second embodiment of the present disclosure.

Recently, as a size of the substrate G to be processed increases, the chamber 11 is also getting scaled up. Further, in order to maintain a vacuum level in the interior of the chamber 11 having such a big size, a thickness of the dielectric window 30 is also getting larger. If the thickness of the dielectric window 30 becomes larger, a distance between RF antennas 31a and 31b and a processing space S within the chamber 11 is increased, so that a combined magnetic field may be easily formed at an intermediate position between the adjacent RF antennas. As a result, it may be difficult to form plasma in one-to-one correspondence to the respective RF antennas. The second embodiment is designed to solve such a problem. In accordance with the second embodiment, a thickness of a portion of the dielectric window 30 corresponding to the respective RF antennas 31a and 31b is set to be smaller than that of the other portion of the dielectric window 30. With this configuration, it is possible to generate plasma 42 in one-to-one correspondence to the respective RF antennas 31a and 31b within the chamber 11.

To elaborate, as shown in FIG. 2, a plasma processing apparatus 40 is different from the plasma processing apparatus 10 of FIG. 1 in the following configuration. That is, instead of forming the circular ring-shaped or circular protrusions 34 made of the dielectric material at the positions on the bottom surface of the dielectric window 30 corresponding to the inter-position of the RF antennas 31a and 31b, circular ring-shaped recesses 41 are formed at positions on the bottom surface of the dielectric window 30 corresponding to the respective RF antennas 31a and 31b. Therefore, the thickness of portions of the dielectric window 30 corresponding to the RF antennas 31a and 31b are set to be smaller than that of the other portion of the dielectric window 30.

In accordance with the second embodiment, since the circular ring-shaped recesses 41 are formed at the positions on the bottom surface of the dielectric window 30 corresponding to the RF antennas 31a and 31b and the thickness of those portions is smaller than that of the other portion of the dielectric window 30, an induced magnetic field stronger than a combined magnetic field is formed directly under the respective RF antennas 31a and 31b. Accordingly, it is possible to generate the plasma 42 within the chamber 11 in one-to-one correspondence to the respective RF antennas 31a and 31b.

In accordance with the second embodiment, the thickness of the dielectric window 30 may be in the range of, e.g., about 20 mm to about 50 mm. Further, the thickness of the portions of the dielectric window 30 where the recesses 41 are formed may be in the range of, e.g., about 10 mm to about 20 mm.

In the second embodiment, the circular ring-shaped recesses 41 are formed along the entire peripheries of the dielectric window 30 so as to correspond to the RF antennas 31a and 31b. However, it may be also possible to form the recesses 41 on a part of the entire peripheries of the dielectric window 30 in consideration of the strength of the dielectric window 30.

FIG. 3 is a cross sectional view schematically illustrating a major configuration of a plasma processing apparatus in accordance with a third embodiment of the present disclosure.

As depicted in FIG. 3, a plasma processing apparatus 50 is different from the plasma processing apparatus 10 of FIG. 1 in the following configuration. That is, instead of forming the circular ring-shaped or circular protrusions 34 made of the dielectric material at the positions on the bottom surface of the dielectric window 30 corresponding to the inter-position of the RF antennas 31a and 31b, circular ring-shaped or circular protrusions 51a made of a material having a magnetic permeability different from that of a dielectric window 30 are formed on a top surface of the dielectric window 30 at positions corresponding to the inter-position of the RF antennas 31a and 31b.

In accordance with the third embodiment, since the circular ring-shaped or circular protrusions 51a made of the material having the magnetic permeability different from that of the dielectric window 30 are provided at the inter-position of the RF antennas 31a and 31b, magnetic force lines in induced magnetic fields formed around the respective RF antennas 31a and 31b may be varied due to the protrusions 51a, so that a generated plasma may also vary. Therefore, a combined magnetic field may not be formed.

Accordingly, induced electric fields corresponding to the respective RF antennas 31a and 31b may be formed within the chamber 11. Then, circular ring-shaped plasma 52 corresponding to the respective RF antennas 31a and 31b may be generated by the induced electric fields.

In accordance with the third embodiment, the plasma can be generated at positions corresponding to the respective RF antennas 31a and 31b, and intensity of the plasma 52 can be controlled by the applied excitation RF_{H}. Thus, it is much easier to control the plasma within the chamber 11.

In accordance with the third embodiment, ferrite, permalloy or the like may be used as the material having the magnetic permeability different from that of the dielectric window 30. The protrusions 51a may be made of, e.g., ferrite.

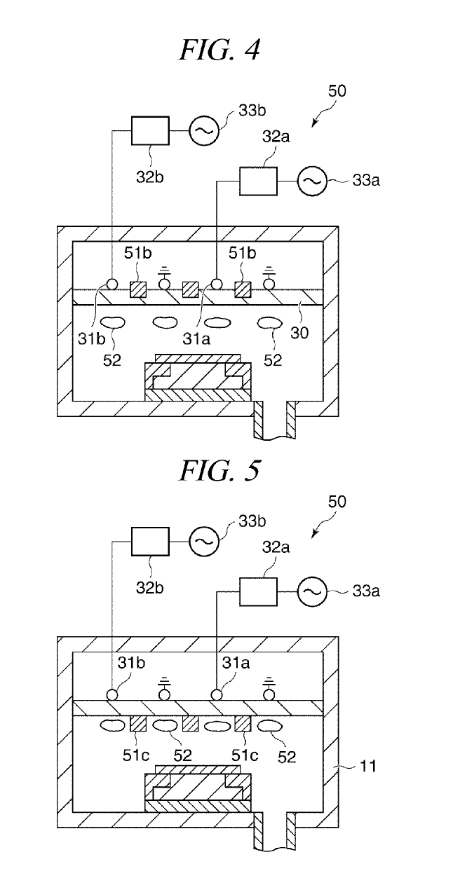

FIG. 4 is a cross sectional view schematically illustrating a major configuration of a modification example of the third embodiment.

As shown in FIG. 4, a plasma processing apparatus 50 is different from the plasma processing apparatus of FIG. 3 in the following configuration. That is, a cross sectional area of a protrusion 51b made of a material having a magnetic permeability different from that of the dielectric window 30 is slightly larger than that of the protrusion 51a. Further, a part of the protrusion 51b is inserted and buried in, e.g., a spot facing portion formed in a top surface of the dielectric window 30.

In accordance with the modification example of the third embodiment, the same effect as obtained in the third embodiment can also be achieved.

Furthermore, in accordance with the modification example of the third embodiment, since the cross sectional area of the protrusion 51b having a circular ring shape is slightly larger than that of the protrusion 51a of the third embodiment, the effect of preventing the combined magnetic field from being formed can be further enhanced. Accordingly, plasma 52 can be generated at positions corresponding to the respective RF antennas 31a and 31b, accurately. Further, since a part of the protrusion 51b is insertion-fitted and buried in the dielectric window 30, it is possible to exactly determine and fix the position of the protrusion 51b.

FIG. 5 is a cross sectional view schematically illustrating a major configuration of another modification example of the third embodiment.

As depicted in FIG. 5, a plasma processing apparatus 50 is different from the plasma processing apparatus of Fig. in the following configuration. That is, a cross sectional area of a circular ring-shaped protrusion 51c is slightly larger than the cross sectional area of the protrusion 51a of the third embodiment. Further, the protrusion 51c is provided on a bottom surface of the dielectric window 30.

In accordance with this another modification example, the same effect as obtained in the third embodiment can still be achieved.

Moreover, in accordance with this another modification example of the third embodiment, since the cross sectional area of the circular ring-shaped protrusion 51c is slightly larger than that of the protrusion 51a of the third embodiment, the effect of preventing a combined magnetic field from being formed can be further enhanced. Accordingly, plasma 52 can be generated at positions corresponding to the respective RF antennas 31a and 31b, accurately.

Further, in accordance with this another modification example of the third embodiment, since the protrusion 51c is exposed to the plasma generated within the chamber 11, it may be desirable to coat the protrusion 51c with, e.g., SiO₂ or yttria. In this way, a lifetime of the protrusion 51c can be extended.

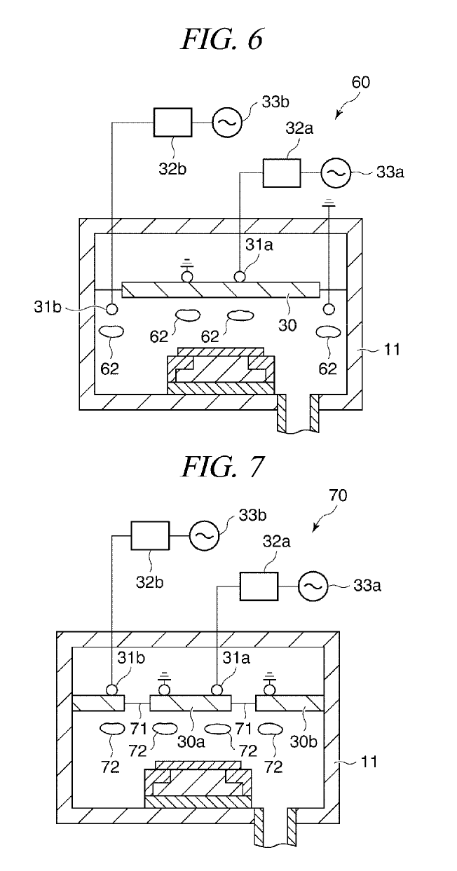

FIG. 6 is across sectional view schematically illustrating a major configuration of a plasma processing apparatus in accordance with a fourth embodiment of the present disclosure.

As shown in FIG. 6, a plasma processing apparatus 60 is different from the plasma processing apparatus 10 of Fig. in the following configuration. That is, instead of forming the protrusions 34 made of the dielectric material and provided at the positions on the bottom surface of the dielectric window 30 corresponding to the inter-position of the RF antennas 31a and 31b, a diameter of the circular ring-shaped RF antenna 31b is set to be very larger than that of the circular ring-shaped RF antenna 31a, and the RF antenna 31b is positioned within the chamber 11. To elaborate, the RF antenna 31b having a diameter larger than the substrate G is positioned outside the dielectric window 30 within the chamber 11.

In accordance with the fourth embodiment, since a gap between the RF antennas 31a and 31b is large, eddy currents caused by induced magnetic fields generated around the RF antennas 31a and 31b do not overlap with each other, so that a combined eddy current may not be generated. Accordingly, induced electric fields and plasma 62 in one-to-one correspondence to the respective RF antennas 31a and 31b may be generated.

In accordance with the fourth embodiment, it may be desirable to coat the RF antenna 31b positioned within the chamber 11 with a dielectric material such as SiO₂ or yttria. In this way, the RF antenna 31b may not be directly exposed to the plasma, so that a lifetime of the RF antenna 31b can be extended.

FIG. 7 is a cross sectional view schematically illustrating a major configuration of a plasma processing apparatus in accordance with a fifth embodiment of the present disclosure.

As illustrated in FIG. 7, a plasma processing apparatus 70 is different from the plasma processing apparatus 10 of FIG. 1 in the following configuration. That is, instead of forming the protrusions 34 made of the dielectric material and provided at the positions on the bottom surface of the dielectric window 30 corresponding to the inter-position of the RF antennas 31a and 31b, the dielectric window 30 is divided into two parts corresponding to RF antennas 31a and 31b, respectively. Further, a metal serving as a conductor, which is grounded, is disposed between the divided dielectric windows 30. The metal 71 may be, but not limited to, aluminum. Desirably, a surface of the aluminum in contact with the plasma may be coated with SiO₂ or yttria.

The circular ring-shaped RF antenna 31a is disposed on a dielectric window 30a in a central portion of the chamber 11, whereas the circular ring-shaped RF antenna 31b is disposed on a dielectric window 30b in an inner peripheral portion of the chamber 11.

In accordance with the fifth embodiment, the dielectric window 30 is divided into the dielectric window 30a positioned in the central portion of the chamber 11 and the dielectric window 30b positioned in the inner peripheral portion of the chamber 11. The metal 71, which is grounded, is disposed between the dielectric windows 30a and 30b. Accordingly, eddy current in induced magnetic fields respectively formed around the RF antennas 31a on the dielectric window 30a and the RF antenna 31b on the dielectric window 30 flows to the ground through the metal 71. Thus, the eddy currents may not be combined and plasma 72 corresponding to the respective RF antennas 31a and 31b can be generated.

In the fifth embodiment, it may be possible to provide a processing gas introduction member in the metal 71 that is disposed between the divided dielectric windows. In such a case, the metal 71 may serve as a shower head.

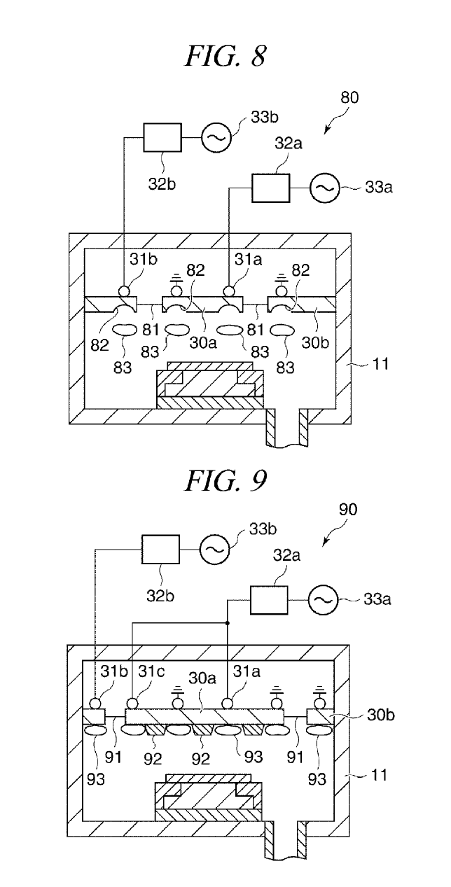

FIG. 8 is a cross sectional view schematically illustrating a major configuration of a plasma processing apparatus in accordance with a sixth embodiment of the present disclosure.

As depicted in FIG. 8, a plasma processing apparatus includes both an inventive feature of the fifth embodiment and an inventive feature of the second embodiment. That is, a dielectric window 30 is divided into dielectric windows 30a and 30b corresponding to RF antennas 31a and 31b, respectively. A metal 81, which is grounded, is disposed between the dielectric windows 30a and 30b. Further, circular ring-shaped recesses 82 are formed in bottom surfaces of the dielectric windows 30a and 30b, so that the thickness of portions of the dielectric windows 30a and 30b where the recesses 82 are formed is set to be smaller than that of the other portions of the dielectric windows 30a and 30b.

In accordance with the sixth embodiment, the dielectric window 30 is divided into the dielectric windows 30a and 30b corresponding to the RF antennas 31a and 31b, respectively. Further, the metal 81, which is grounded, is disposed between the dielectric windows 30a and 30b. The circular ring-shaped recesses 82 are formed on the bottom surfaces of the dielectric windows 30a and 30b corresponding to the respective RF antennas 31a and 31b. Moreover, the thickness of the portions of the dielectric windows 30a and 30b where the recesses 82 are formed is set to be smaller than that of the other portions of the dielectric windows 30a and 30b. Therefore, eddy current may be suppressed by the metal 81 grounded and the plasma may be generated in the chamber directly under the RF antennas by the induced magnetic fields stronger than the combined magnetic field by thinning the dielectric window. Due to the synergy effect of the above, the plasma 83 can be generated at positions corresponding to the respective RF antennas 31a and 31b within the chamber 11. Furthermore, since it is possible to generate the plasma 83 at desired positions within the chamber 11 according to the positions of the RF antennas 31a and 31b, it is much easier to control the plasma within the chamber 11.

FIG. 9 is a cross sectional view schematically illustrating a major configuration of a plasma processing apparatus in accordance with a seventh embodiment of the present disclosure.

As shown in FIG. 9, a plasma processing apparatus 90 includes both the inventive feature of the fifth embodiment and the inventive feature of the first embodiment. That is, the dielectric window 30 is divided into dielectric windows 30a and 30b corresponding to RF antennas 31a and 31b, respectively. A metal 91, which is grounded, is disposed between the dielectric windows 30a and 30b. Further, a RF antenna 31c having a diameter larger than the RF antenna 31a is provided on the dielectric window 30a. Furthermore, protrusions 92 made of a dielectric material are provided on a bottom surface of the dielectric window 30a so as to correspond to the inter-position of the RF antennas 31a and 31c.

In accordance with the seventh embodiment, the dielectric window 30 is divided into the dielectric windows 30a and 30b corresponding to the RF antennas 31a and 31b, respectively. The metal 91, which is grounded, is disposed between the dielectric windows 30a and 30b. Further, the RF antenna 31c having the larger diameter than the RF antenna 31a is provided on the dielectric window 30a. Furthermore, the protrusions 92 made of, e.g., glass are provided on the bottom surface of the dielectric window 30a so as to correspond to the inter-position of the RF antennas 31a and 31c. Therefore, eddy current may be suppressed by the metal 81 grounded and plasma may be prevented from existing at a position where a combined magnetic field may be formed. Accordingly, due to the synergy effect of the above, it is possible to generate plasma 93 corresponding to the respective RF antennas 31a to 31c within the chamber 11. In addition, since it is possible to generate the plasma at desired positions within the chamber 11 so as to correspond to the respective RF antennas 31a to 31c, it is much easier to control the plasma within the chamber 11.

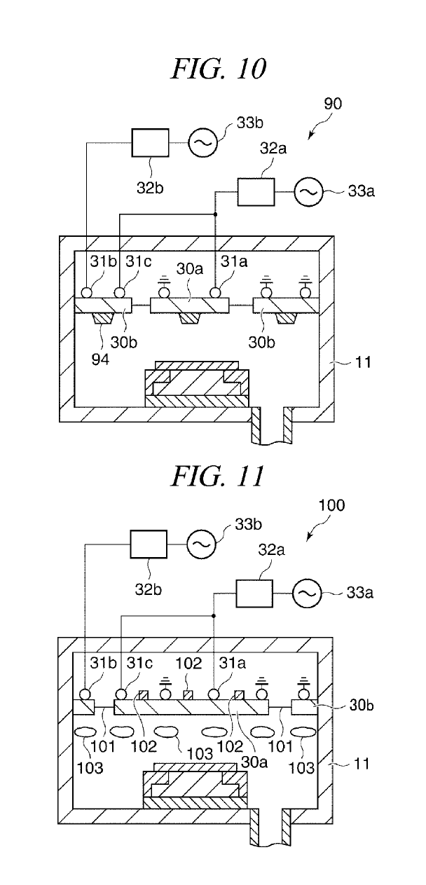

FIG. 10 is a cross sectional view schematically illustrating a major configuration of a modification example of the seventh embodiment.

As illustrated in FIG. 10, a plasma processing apparatus 90 is different from the plasma processing apparatus of FIG. 9 in the following configuration. That is, instead of forming the RF antenna 31c on the outer periphery portion of the RF antenna 31a on the dielectric window 30a, the RF antenna 31c having a diameter smaller than the RF antenna 31b may be provided on the dielectric window 30b positioned in the inner periphery portion of the chamber 11. Further, a circular ring-shaped protrusion 94 made of glass is provided on a bottom surface of the dielectric window 30b so as correspond to the inter-position of the RF antennas 31b and 31c.

In this modification example, the same effect as obtained in the seventh embodiment can also be achieved.

FIG. 11 is a cross sectional view schematically illustrating a major configuration of a plasma processing apparatus in accordance with an eighth embodiment of the present disclosure.

As depicted in FIG. 11, a plasma processing apparatus 100 includes both the inventive feature of the fifth embodiment and the inventive feature of the third embodiment. That is, the dielectric window 30 is divided into the dielectric window 30a in the central portion of the chamber and the dielectric window 30b in the inner peripheral portion of the chamber 11. A metal 101, which is grounded, is disposed between the dielectric windows 30a and 30b. Further, the RF antenna 31c having a diameter larger than the RF antenna 31a is provided on the dielectric window 30a. Furthermore, circular ring-shaped or circular protrusions 102 having a magnetic permeability different from that of the dielectric window 30a are provided on a top surface of the dielectric window 30a so as to correspond to the inter-position of the RF antennas 31a and 31c.

In accordance with the eighth embodiment, the dielectric window 30 is divided into the dielectric windows 30a and 30b so as to correspond to the RF antennas 31a and 31b, respectively. The metal 101, which is grounded, is disposed between the dielectric windows 30a and 30b. Further, the RF antenna 31c having the larger diameter than the RF antenna 31a is provided on the dielectric window 30a. Furthermore, the circular ring-shaped or circular protrusions 102 having the magnetic permeability different from that of the RF antenna 31a are provided on the top surface of the dielectric window 30a so as to correspond to the inter-position of the RF antennas 31a and 31c. Therefore, eddy current may be suppressed by the metal 101 grounded and magnetic force lines may be cut by the protrusions 102 having the magnetic permeability different from that of the dielectric window 30a. Accordingly, it is possible to generate plasma 103 corresponding to the respective RF antennas 31a to 31c within the chamber 11. In addition, since it is possible to generate the plasma at desired positions within the chamber 11 so as to correspond to the respective RF antennas 31a to 31c, it is much easier to control the plasma within the chamber 11.

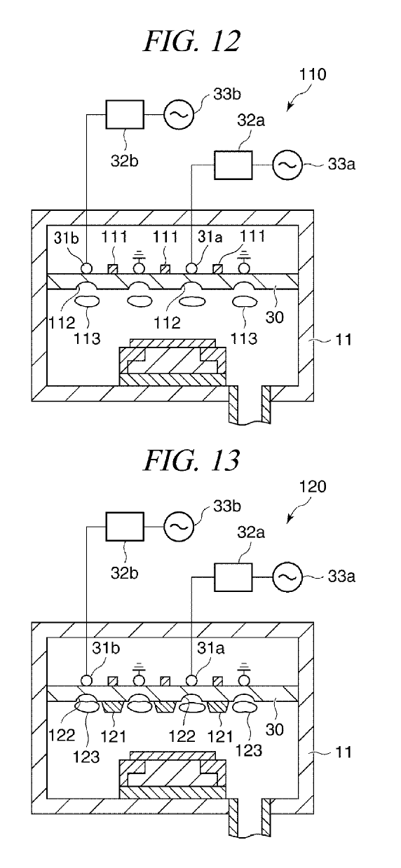

FIG. 12 is a cross sectional view schematically illustrating a major configuration of a plasma processing apparatus in accordance with a ninth embodiment of the present disclosure.

As shown in FIG. 12, a plasma processing apparatus 110 includes both the inventive feature of the third embodiment and the inventive feature of the second embodiment. That is, circular ring-shaped or circular protrusions 111 made of a material having a magnetic permeability different from that of a dielectric window 30 are provided at the inter-position of the RF antennas 31a and 31b. Further, recesses 112 are formed in a bottom surface of the dielectric window 30 so as to correspond to the RF antennas 31a and 31b, respectively. Furthermore, the thickness of portions of the dielectric window 30 where the recesses 112 are formed is set to be smaller than that of the other portion of the dielectric window 30.

In accordance with the ninth embodiment, the circular ring-shaped or circular protrusions 111 having the magnetic permeability different from that of the dielectric window 30 are provided on the top surface of the dielectric window 30 so as to correspond to the inter-position of the RF antennas 31a and 31b. Further, the recesses 112 are formed in the bottom surface of the dielectric window 30 so as to correspond to the respective RF antennas 31a and 31b. Furthermore, the thickness of the portions where the recesses 112 are formed is set to be smaller than that of the other portion of the dielectric window 30. Therefore, the magnetic force lines may be cut by the protrusions 111 having the magnetic permeability different from that of the dielectric window 30 and the plasma may be generated directly under the RF antennas by induced magnetic fields stronger than the combined magnetic field by thinning the dielectric window 30. Accordingly, due to the synergy effect of the above, it is possible to generate plasma 113 corresponding to the respective RF antennas 31a and 31b.

FIG. 13 is a cross sectional view schematically illustrating a major configuration of a plasma processing apparatus in accordance with a tenth embodiment of the present disclosure.

As illustrated in FIG. 13, a plasma processing apparatus 120 includes both the inventive feature of the second embodiment and the inventive feature of the first embodiment. That is, circular ring-shaped or circular protrusions 121 made of a dielectric material are provided on a bottom surface of the dielectric window 30 so as to correspond to the inter-position of the RF antennas 31a and 31b. Further, recesses 122 are formed in the bottom surface of the dielectric window 30 so as to correspond to the respective RF antennas 31a and 31b. A thickness of portions of the dielectric window 30 where the recesses 122 are formed is set to be smaller than that of the other portion of the dielectric window 30.

In accordance with the tenth embodiment, the circular ring-shaped protrusions 121 are provided on the bottom surface of the dielectric window 30 so as to correspond to the inter-position of the RF antennas 31a and 31b. The circular ring-shaped recesses 122 are also formed in the bottom surface of the dielectric window 30 so as to correspond to the respective RF antennas 31a and 31b. Further, the thickness of the portions of the dielectric window 30 where the recesses 122 are formed is set to be smaller than that of the other portion of the dielectric window 30. Therefore, plasma may be prevented from existing at a position where a combined magnetic field may be formed by the protrusions 121 made of the dielectric material. Further, plasma may be formed directly under the RF antennas by induced magnetic fields stronger than the combined magnetic field by thinning the dielectric window 30. Due to the synergy effect of the above, it is possible to generate plasma 123 corresponding to the respective RF antennas 31a and 31b. Thus, it is much easier to control the plasma within the chamber 11, as in the above-described embodiments.

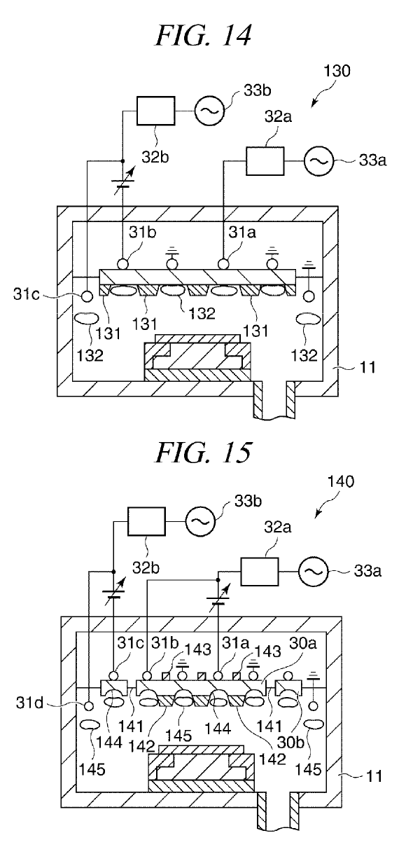

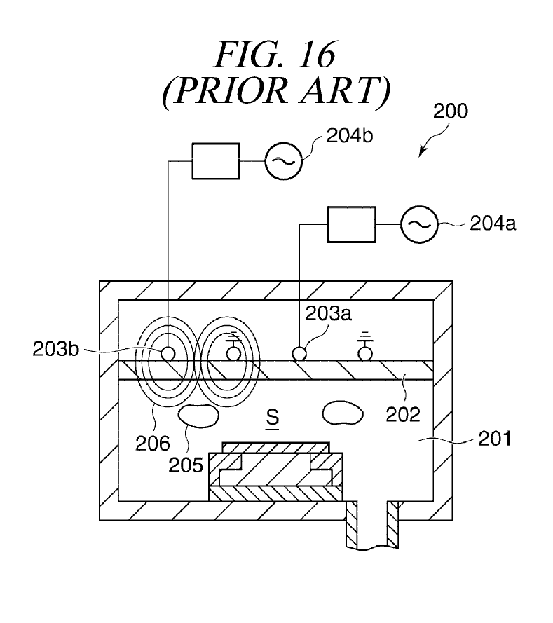

FIG. 14 is a cross sectional view schematically illustrating a major configuration of a plasma processing apparatus in accordance with an eleventh embodiment of the present disclosure.

As depicted in FIG. 14, a plasma processing apparatus 130 includes both the inventive feature of the first embodiment and the inventive feature of the fourth embodiment. That is, the RF antenna 31c having a diameter larger than the RF antenna 31b is provided within a chamber so as to be located outside the dielectric window 30. Further, circular ring-shaped protrusions 131 made of a dielectric material are provided on a bottom surface of the dielectric window 30 at positions corresponding to the inter-position of the RF antennas 31a to 31c.

In accordance with the eleventh embodiment, plasma may be prevented from existing at a position where a combined magnetic field may be formed by the protrusions 131 made of the dielectric material. Further, the combined magnetic field may not be generated by locating the RF antenna 31c in the chamber 11 so as to be distanced apart from the RF antenna 31b. Due to the synergy effect of the above, it is possible to generate plasma 132 corresponding to the respective RF antennas 31a to 31c. Thus, as in the above-described embodiments, it is much easier to control the plasma within the chamber 11.

In the eleventh embodiment, although the RF antennas 31b and 31c are connected with the same high frequency power supply 33b, it may be also possible to provide the high frequency power supplies for the respective RF antennas 31b and 31c.

FIG. 15 is a cross sectional view schematically illustrating a major configuration of a plasma processing apparatus in accordance with a twelfth embodiment of the present disclosure.

As shown in FIG. 15, a plasma processing apparatus 140 includes all of the inventive features of the first to the fifth embodiment. That is, the dielectric window 30 is divided into the dielectric window 30a in the central portion of the chamber 11 and the dielectric window 30b in the inner peripheral portion of the chamber 11. Further, a metal 141, which is grounded, is disposed between the dielectric windows 30a and 30b. Circular ring-shaped or circular protrusions 142 made of a dielectric material are provided on a bottom surface of the dielectric window 30a at positions corresponding to the inter-position of the RF antennas 31a and 31b. Further, circular ring-shaped or circular protrusions 143 made of a material having a magnetic permeability different from that of the dielectric window 30a are provided on a top surface of the dielectric window 30a. In addition, recesses 144 are formed at bottom surfaces of the dielectric windows 30a and 30b so as to correspond to the respective RF antennas 31a to 31c. The thickness of portions of the dielectric windows 30a and 30b where the recesses 144 are formed is set to be smaller than that of the other portions of the dielectric windows 30a and 30b. Furthermore, a RF antenna 31d having a diameter larger than the RF antenna 31c provided on the dielectric window 30b is provided within the chamber 11 so as to be located outside the dielectric window 30b.

In accordance with the twelfth embodiment of the present disclosure, the plasma processing apparatus 140 have all the inventive features of the first to the fifth embodiments. Thus, due to the synergy effects of those inventive features, it is possible to generate plasma 145 in one-to-one correspondence to the respective RF antennas 31a to 31d, accurately. Accordingly, as in the other embodiments as described above, it is much easier to control a plasma distribution within the chamber 11.

In the twelfth embodiment, although the RF antennas 31a and 31b are connected with the same high frequency power supply 33a, and the RF antennas 31c and 31d are connected with the same high frequency power supply 33b, it may be also possible to provide the high frequency power supplies for the respective RF antennas 31a to 31d. That is, a method for applying high frequency powers may not be particularly limited. Furthermore, a method for dividing the dielectric window may not also be particularly limited.

In the aforementioned embodiments, the substrate on which the plasma process is performed may not be limited to a glass substrate for a liquid crystal display (LCD), but various kinds of substrates for use in, e.g., an electro luminescence (EL) display and a flat panel display (FPD) such as a plasma display panel (PDP) may also be used.

What is claimed is:

1. A plasma processing apparatus comprising:
an evacuable processing chamber for performing therein a plasma process on a substrate;
a substrate mounting table for mounting thereon the substrate within the processing chamber;
a dielectric window provided to face the substrate mounting table via a processing space;
a multiple number of high frequency antennas disposed in a space adjacent to the processing space with the dielectric window positioned therebetween;
a gas supply unit for supplying a processing gas into the processing space;
a high frequency power supply for applying a high frequency power to the multiple number of high frequency antennas to thereby generate plasma of the processing gas by an inductive coupling; and
a combination preventing member for preventing induced magnetic fields corresponding to the multiple number of high frequency antennas from being combined with each other.

2. The plasma processing apparatus of claim 1, wherein the combination preventing member is a protrusion made of a dielectric material and provided on a surface of the dielectric window facing the processing space, and
the combination preventing member is located at a position corresponding to an inter-position of the multiple number of high frequency antennas.

3. The plasma processing apparatus of claim 1, wherein a thickness of a portion of the dielectric window corresponding to the multiple number of high frequency antennas is smaller than that of the other portion of the dielectric window.

4. The plasma processing apparatus of claim 1, wherein a protrusion made of a material having a magnetic permeability different from that of the dielectric window is provided at an inter-position of the multiple number of high frequency antennas.

5. The plasma processing apparatus of claim 4, wherein the protrusion is provided on a surface of the dielectric window facing the processing space or on a surface of the dielectric window opposite to the processing space.

6. The plasma processing apparatus of claim 4, wherein a part of the protrusion is inserted and buried in the dielectric window.

7. The plasma processing apparatus of claim 1, wherein the multiple number of high frequency antennas are spaced apart from each other at a distance enough for preventing the induced magnetic fields corresponding to the multiple number of high frequency antennas from being combined with each other.

8. The plasma processing apparatus of claim 1, wherein the dielectric window is divided so as to correspond to the multiple number of high frequency antennas, and
a conductor, which is grounded, is disposed between the divided dielectric windows.
